(19) United States
(12) Patent Application Publication
(10) Pub. No.: US 2016/0334560 A1
(43) Pub. Date: Nov. 17, 2016

(54) DISPLAY DEVICE INCLUDING ACCOMMODATING MEMBER

(71) Applicant: Samsung Display Co., Ltd., Yongin-si (KR)

(72) Inventors: Junwoo YOU, Seongnam-si (KR); Seki PARK, Hwaseong-si (KR)

(21) Appl. No.: 14/927,616

(22) Filed: Oct. 30, 2015

(30) Foreign Application Priority Data
May 12, 2015 (KR) 10-2015-0066088

(51) Int. Cl. F21V 8/00; H05K 1/02; H05K 5/00

(52) U.S. Cl. CPC G02B 6/009; H05K 5/0017; H05K 1/028; G02B 6/0085; G02B 6/0091; G02B 6/005

(57) ABSTRACT

A display device includes: a display panel including a display area in which an image is displayed and a non-display area around the display area; and an accommodating member in which the display panel is accommodated. The accommodating member includes a bottom portion on which the display panel is supported. The bottom portion of the accommodating member extends to define a side portion of the accommodating member bent to cover a side surface of the display panel. The side portion defined by the extended bottom portion extends to define a cover portion bent to cover the non-display area of the display panel.

This application claims priority to Korean Patent Application No. 10-2015-0066088, filed on May 12, 2015, and all the benefits accruing therefrom under 35 U.S.C. §119, the disclosure of which is incorporated herein in its entirety by reference.

### BACKGROUND

1. Field

Exemplary embodiments of the invention relate to a display device, and more particularly, to a display device reduced in the number of components thereof and capable of the convenient assembly thereof.

2. Description of the Related Art

Display devices are classified into types including liquid crystal display (“LCD”) devices, organic light emitting diode (“OLED”) display devices, plasma display panel (“PDP”) devices, electrophoretic display (“EPD”) devices, and the like, based on a light emitting scheme thereof.

A display device has a structure in which a display panel, various frames configured to support and/or accommodate the display panel, and various optical sheets for enhancing optical characteristics of the display panel are sequentially stacked.

Accordingly, in the display device, a process of assembling the components, such as the display panel, the various frames and the optical sheets, is relatively significant in cost and time. In this regard, where a display device includes a relatively large number of components, a manufacturing process may be complicated and manufacturing costs may increase.

### SUMMARY

One or more exemplary embodiment of the invention is directed to a display device reduced in the number of components thereof and capable of the convenient assembly thereof.

According to an exemplary embodiment of the invention, a display device includes: a display panel including a display area in which an image is displayed and a non-display area around the display area and in which the image is not displayed; and an accommodating member in which the display panel is accommodated. The accommodating member includes: a bottom portion on which the display panel is supported. The bottom portion of the accommodating member extends to define a side portion of the accommodating member, the side portion bent from the bottom portion to cover a side surface of the display panel. The side portion defined by the extended bottom portion extends to define a cover portion of the accommodating member, the cover portion bent from the side portion to cover the non-display area of the display panel.

The display device may further include a reflective member disposed on a surface of the accommodating member, the surface facing the display panel.

The reflective member may be disposed on a surface of the bottom portion of the accommodating member.

The reflective member may include one or more of aluminum (Al), silver (Ag), gold (Au), titanium oxide, aluminum paste, aluminum powder, silicon oxide, aluminum oxide, zirconium oxide, magnesium fluoride, barium sulfate, and calcium carbonate.

The accommodating member may be a reflective sheet.

The display device may further include a flexible printed circuit board (“FPCB”) connected to the display panel. The side portion of the accommodating member defined by the extended bottom portion thereof defines an aperture through which the flexible printed circuit board is extended.

The display device may further include a flexible printed circuit board connected to the display panel, and an insulating member on the flexible printed circuit board. The cover portion of the accommodating member defined by the extended side portion thereof may include a first cover portion extended from the side portion at a first side of the bottom portion and a second cover portion extended from the side portion at a second side of the bottom portion opposite to the first side thereof, the first and second cover portions overlapping each other in a cross-sectional thickness direction. In the cross-sectional thickness direction, the flexible printed circuit board connected to the display panel and the insulating member on the flexible printed circuit board connected to the display panel may each be disposed between the overlapping first and second cover portions

The display device may further include a light source unit which is accommodated in the accommodating member and generates and provides light to the display panel.

The light source unit may include a light source, and a light source substrate to which the light source is fixed.

The display device may further include a fixing member between the accommodating member and the light source substrate.

The accommodating member may define an aperture through which a portion of the light source substrate is exposed from the accommodating member.

The display device may further include a heat dissipation member attached to the exposed portion of the light source substrate.

The display device may further include a light guide plate between the display panel and the bottom portion of the accommodating member.

The display device may further include a fixing member between the accommodating member and the light guide plate.

The display device may further include an optical sheet between the display panel and the light guide plate.

The display device may further include a light source unit which is accommodated in the accommodating member and generates and provides light to the display panel, and a light shielding member between the display panel and the light guide plate.

In the display device, the cover portion of the accommodating member defined by the extended side portion thereof may include a first cover portion extended from the side portion at a first side of the bottom portion and a second cover portion extended from the side portion at a second side of the bottom portion opposite to the first side thereof, the first and second cover portions overlapping each other in a cross-sectional thickness direction. In the cross-sectional thickness direction, the first and second cover portions may overlap each other at a same side of or at opposing sides of the light shielding member.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features of the present disclosure of invention will be more clearly understood from the following detailed description taken in conjunction with the accompanying drawings, in which:

FIG. 1 is an exploded perspective view illustrating an exemplary embodiment of a display device according to the invention;

FIG. 2 is a cross-sectional view taken along line I-II of FIG. 1;

FIGS. 3 and 4 are cross-sectional views respectively illustrating other exemplary embodiments of display devices according to the invention; and

FIGS. 5, 6, 7, 8 and 9 are plan views illustrating an exemplary embodiment of assembling a display device according to the invention.

### DETAILED DESCRIPTION

Exemplary embodiments will now be described more fully hereinafter with reference to the accompanying drawings.

Although the invention can be modified in various manners and have several embodiments, exemplary embodiments are illustrated in the accompanying drawings and will be mainly described in the specification. However, the scope of the invention is not limited to the exemplary embodiments and should be construed as including all the changes, equivalents, and substitutions included in the spirit and scope of the invention.

Throughout the specification, when an element is referred to as being “connected” to another element, the element is “physically connected” to the other element, or “electrically connected” to the other element with one or more intervening elements interposed therebetween. When an element is referred to as being “directly connected” to another element, the element is “directly physically connected” to the other element or “directly electrically connected” to the other element with no intervening elements interposed therebetween.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second” and the like, may be used herein to describe various elements, components, areas, layers and/or sections, these elements, components, areas, layers and/or sections should not be limited by these terms. These terms are only used to distinguish one element, component, area, layer or section from another element, component, area, layer or section. Thus, a first element, component, area, layer or section discussed below could be termed a second element, component, area, layer or section without departing from the teachings of exemplary embodiments.

When it is determined that a detailed description may make the purpose of the invention unnecessarily ambiguous in the description of the invention, such a detailed description will be omitted. In addition, the same components and corresponding components are given the same reference numeral.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of a display device according to the invention will be explained with respect to a liquid crystal display (“LCD”) device. However, the display device is not limited thereto, and features of the invention may also be applied to an organic light emitting diode (“OLED”) display device or a plasma display panel (“PDP”) device.

Throughout the specification, the display device will be described under the assumption that the display device includes an edge-type backlight unit. According to embodiments, the display device may also include a direct-type backlight unit or a corner-type backlight unit.

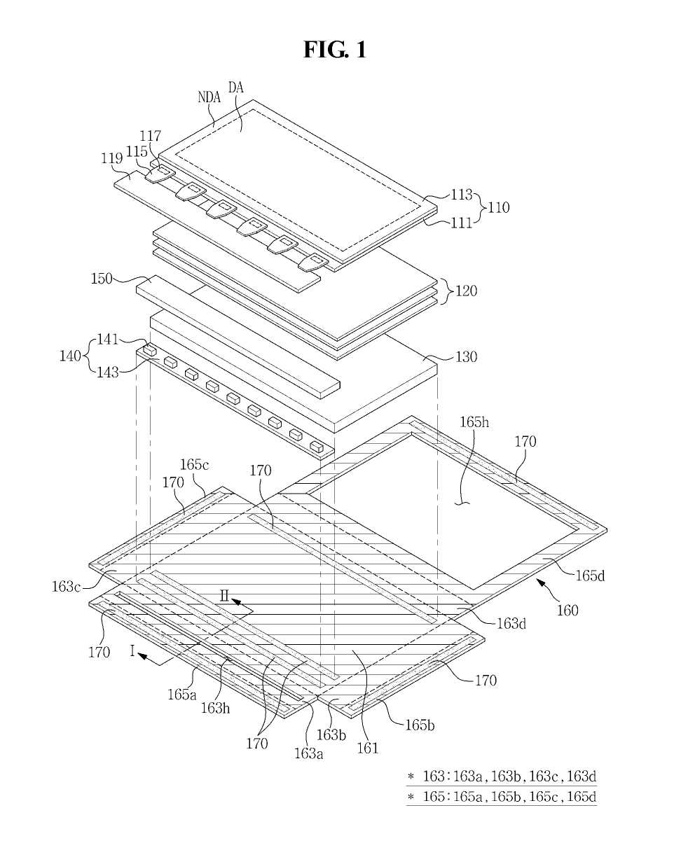

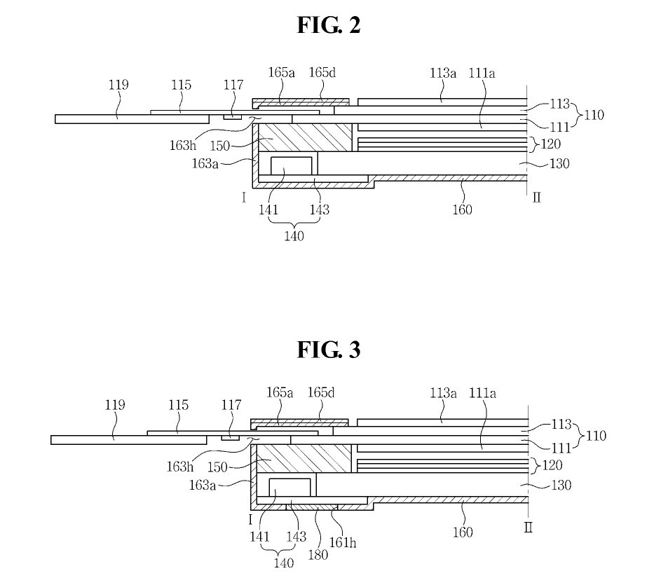

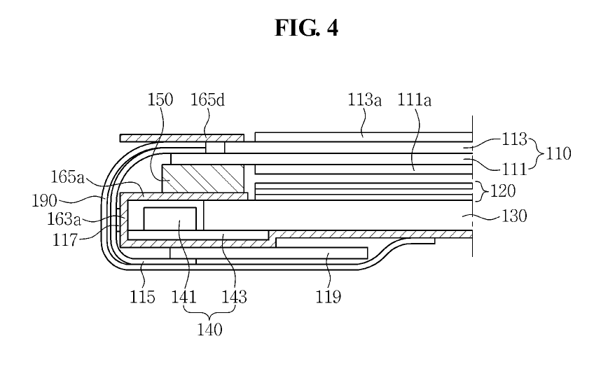

FIG. 1 is an exploded perspective view illustrating an exemplary embodiment of a display device according to the invention. FIG. 2 is a cross-sectional view taken along line I-II′ of FIG. 1. FIGS. 3 and 4 are cross-sectional views respectively illustrating other exemplary embodiments of display devices according to the invention. FIGS. 2-4 may be considered as illustrating an assembled state of the display device.

Referring to FIGS. 1 and 2, the exemplary embodiment of the display device according to the invention includes a display panel 110, an optical sheet 120, a light guide plate 130, a light source unit 140, a light shielding member 150, an accommodating member 160, a plurality of fixing (e.g., adhesive) members 170, and the like.

The display panel 110 may be provided in a quadrangular planar shape and may display an image using light. The display panel 110 may include a display area DA in which an image is displayed, and a non-display area NDA around the display area DA and in which the image is not displayed.

The display panel 110 may include a first display substrate 111, a second display substrate 113 opposing the first display substrate 111, and an image display layer such as a liquid crystal layer (not illustrated) between the first and second display substrates 111 and 113.

The first display substrate 111 may include a pixel electrode provided in plural and arranged in a matrix form on a first base substrate thereof, a thin film transistor applying a driving voltage to each of the pixel electrodes on the first base substrate, and various signal lines for driving the pixel electrode and the thin film transistor on the first base substrate.

The second display substrate 113 may be disposed to oppose the first display substrate 111, and may include a common electrode including or formed of a transparent conductive material, and a color filter, on a second base substrate thereof. The color filter may include red, green and blue color filters, by way of example, but the invention is not limited thereto.

The liquid crystal layer (not illustrated) may be interposed between the first and second display substrates 111 and 113, and orientations of liquid crystal molecules thereof may be rearranged by an electric field formed between the pixel electrode and the common electrode. The rearranged liquid crystal layer may adjust a level of transmittance of light emitted thereby from among light generated and provided from a backlight unit. The light having the adjusted level of transmittance may be transmitted through the color filter, and an image may be displayed outwardly. The backlight unit which generates and provides light to the display panel 110 may include, but is not limited to, the optical sheet 120, the light guide plate 130 and the light source unit 140.

A lower polarizing plate 111a and an upper polarizing plate 113a may further be disposed on a lower surface of the first display substrate 111 and an upper surface of the second display substrate 113, respectively. The upper polarizing plate 113a and the lower polarizing plate 111a may each have a planar area corresponding to a planar area of the display panel 110 in size.

The upper polarizing plate 113a may allow a predetermined component of polarized light from among externally supplied light to pass therethrough, and may absorb or block the remainder of the externally supplied light. The lower polarizing plate 111a may allow a predetermined component of polarized light from among the light emitted from the backlight unit to pass therethrough, and may absorb or block the remainder of the light emitted from the backlight unit.

A driving circuit board 119 may be disposed laterally extended from at least one side of the display panel 110 in the plan view. The driving circuit board 119 may provide various control signals and power signals for driving the display panel 110 to the display panel 110.

The display panel 110 and the driving circuit board 119 may be electrically connected to one another by at least one flexible printed circuit board (“FPCB”) 115. The FPCB 115 may be in the form of a chip-on-film (“COF”) or a tape-carrier-package (“TCP”), and the number of FPCBs 115 may vary based on, for example, a size and a driving scheme, of the display panel 110.

A driving chip 117 may be mounted on the FPCB 115. The driving chip 117 may generate various driving signals for driving the display panel 110. The driving chip 117 may be a single chip in which a timing controller and a data driving circuit are integrated with one another, and may also be referred to as, for example, a driver integrated circuit (“IC”) or a source integrated circuit (“IC”).

The optical sheet 120 may be disposed on the light guide plate 130, and may serve to diffuse or collimate light transmitted from the light guide plate 130. The optical sheet 120 may collectively include a diffusion sheet, a prism sheet and a protective sheet, but the invention is not limited thereto. The diffusion sheet, the prism sheet and the protective sheet may be sequentially stacked on the light guide plate 130.

The prism sheet may collimate light guided by the light guide plate 130, the diffusion sheet may diffuse light collimated by the prism sheet, and the protective sheet may protect the prism sheet. Light having passed through the protective sheet may be supplied to the display panel 110.

The light guide plate 130 may uniformly supply light, generated and emitted from the light source unit 140, to the display panel 110. The light guide plate 130 may have a quadrangular planar shape. According to exemplary embodiments, the light guide plate 130 may have various shapes including, for example, a predetermined groove or a protrusion defined therein or thereon, based on a position of a light source of the light source unit 140.

The light guide plate 130 is described herein as having a planar shape, that is, a plate, for ease of description. While the light guide plate 130 is described as a plate, such as having a relatively large cross-sectional thickness for ease of description, the invention is not limited thereto. According to exemplary embodiments, the light guide plate 130 may be provided in a sheet or film shape for which the cross-sectional thickness is smaller than that of the plate and is relatively small as compared to the planar size thereof, to achieve slimness of the display device. The light guide plate 130 is to be understood as having a concept that includes not only a plate but also a film which guides light provided from the light source unit 140.

The light guide plate 130 may include or be formed of a light-transmissive material, for example, polycarbonate (“PC”) or an acrylic resin such as poly(methyl methacrylate) (“PMMA”) to help guide light efficiently.

The light source unit 140 may include a light source 141, and a light source substrate 143 on which the light source 141 is mounted.

The light source 141 may be disposed at an edge or a light-incident side surface of the light guide plate 130. In other words, the light source 141 may emit light at least laterally toward the edge or the light-incident side surface of the light guide plate 130. The light source 141 may include a light emitting diode (“LED”) or an LED chip. In an exemplary embodiment, for example, the light source 141 may be a gallium nitride (GaN)-based LED which generates and emits blue light. The light source 141 may be provided in plural and arranged along a length of the light source substrate 143. A number of light sources 141 may vary based on, for example, a size and luminance uniformity, of the display panel 110.

The light source substrate 143 may be one of a printed circuit board (“PCB”), a metal printed circuit board (“MPCB”) and a metal core printed circuit board (“MCPCB”).

The accommodating member 160 may include a bottom portion 161, a side portion (or sidewall) 163 which is extended from the bottom portion 161 and a cover portion which is extended from the side portion 163. The portions of the accommodating member 160 are described in more detail below.

In the display device according to the exemplary embodiment, the light source substrate 143 is described as being disposed on and attached to the bottom portion 161 of the accommodating member 160. However, the position of the light source substrate 143 is not limited thereto. The light source substrate 143 may be attached to the side portion 163 of the accommodating member 160, or may be disposed between the light source 141 and the light shielding member 150.

Referring to FIG. 3, in another exemplary embodiment of a display device according to the invention, a portion of a light source substrate 143 may be exposed externally of the accommodating member 160. The bottom portion 161 defines an aperture 161h through which a portion of the light source substrate 143 is exposed.

In addition, a heat dissipation member 180 may be disposed on a portion of the light source substrate 143 which is exposed through the aperture 161h defined by the bottom portion 161. The heat dissipation member 180 may be, for example, a heat dissipation tape, but the invention is not limited thereto. The heat dissipation member 180 may be configured to relatively rapidly dissipate heat generated in the light source unit 140 externally to outside the display device.

In still another exemplary embodiment of a display device according to the invention, where the light source substrate 143 is attached to the side portion 163 of the accommodating member 160, the side portion 163 of the accommodating member 160 may define an aperture (not illustrated), through which the light source substrate 143 is exposed, similar to that shown for the aperture 161h in the bottom portion 161.

The light source unit 140 may be disposed at one, two or four side portions of the light guide plate 130 based on, for example, a size and luminance uniformity, of the display panel 110. In other words, the light source unit 140 may be disposed adjacent to an edge of the light guide plate 130 in the plan view.

Although not illustrated, a wavelength converting unit may be disposed between a light incident surface of the light guide plate 130 and the light source unit 140. The wavelength converting unit may include a light-wavelength converting material. In an exemplary embodiment, for example, the wavelength converting unit may convert a wavelength of blue light emitted from a blue LED light source to obtain white light therefrom.

Referring to FIGS. 1, 2 and 3, the light shielding member 150 may be disposed on the light source unit 140. The light shielding member 150 may be, for example, a light shielding tape. The light shielding member 150 may serve to reduce or effectively prevent the external leakage of light that is emitted from the light source 141 through an aperture defined in the accommodating member 160. In addition, the light shielding member 150 may be disposed between the display panel 110 and the light guide plate 130 so as to maintain a predetermined gap therebetween in a cross-sectional thickness direction of the display device.

The accommodating member 160 may maintain an overall framework of the display device, and may serve to protect various components accommodated therein.

The accommodating member 160 may include the bottom portion 161 having a quadrangular planar shape and supporting various components such as the display panel 110, the side portion 163 extended to be bent from each edge of the bottom portion 161 to cover a side surface of the display panel 110, and the cover portion 165 extended to be bent from the side portion 163 to cover the non-display area NDA of the display panel 110. As a single unitary accommodating member 160, the bottom portion 161 may extend to define both the side portion 163 and the cover portion 165.

In detail, the collective side portion (or sidewall) 163 may include a first side portion 163a, a second side portion 163b, a third side portion 163c and a fourth side portion 163d. The collective cover portion 165 may include a first cover portion 165a extending from the first side portion 163a, a second cover portion 165b extending from the second side portion 163b, a third cover portion 165c extending from the third side portion 163c, and a fourth cover portion 165d extending from the fourth side portion 163d.

As used herein, portions of the accommodating member 160 indicated by dotted lines in the drawings may indicate fold lines at which the accommodating member 160 is folded such as at 90 degrees. Referring to the dotted lines, each of the first through fourth side portions 163a-163d may be defined by extended portions of the bottom portion 161. Further referring to the dotted lines, each of the first to fourth cover portions 165a-165d may be respectively defined by extended portions of the first through fourth side portions 163a-163d.

The accommodating member 160 may include a reflective member disposed on a surface thereof. In particular, the reflective member may be disposed on a surface of the bottom portion 161 that faces the display panel 110. The bottom portion 161 surfaces which faces the display panel 110 may be considered an inner surface of the accommodating member 160.

The reflective member may include one or more of the following: aluminum (Al), silver (Ag), gold (Au), titanium oxide, aluminum paste, aluminum powder, silicon oxide, aluminum oxide, zirconium oxide, magnesium fluoride, barium sulfate, and calcium carbonate. In an exemplary embodiment, for example, the accommodating member 160 may be a reflective sheet.

A side portion among the first through fourth side portions 163a-163d (for example, the first side portion 163a) of the accommodating member 160 may define an aperture 163h through which the FPCB 115, connected to the display panel 110, is extended such as to be drawn in or out of the aperture 163h. In addition, a cover portion among the first to fourth cover portions 165a-165d (for example, the fourth cover portion 165d) of the accommodating member 160 may define an opening 165h through which the display area DA of the display panel 110 is exposed.

In FIGS. 1 and 2, the first and fourth cover portions 165a and 165d are disposed at a same side of the light shielding member 150, but the invention is not limited thereto. A distal end of the fourth cover portion 165d overlaps the first cover portion 165a at the first side portion 163a.

A fixing member such as an adhesive member 170 may be disposed on the accommodating member 160. The adhesive member 170 may serve to fix various components to the accommodating member 160. The adhesive member 170 may be, for example, a double-sided tape. The adhesive member 170 may be disposed on the bottom portion 161, and the first, second, third and fourth cover portions 165a, 165b, 165c and 165d.

Referring to FIG. 4, in yet another exemplary embodiment of a display device according to the invention, the first and fourth cover portions 165a and 165d are disposed at different sides of the light shielding member 150. The first cover portion 165a may cover an upper portion of a light source 141 such that a light source 141 is enclosed. In addition, an edge of a display panel 110 may be disposed on the first cover portion 165a, and a light shielding member 150 may be disposed between the display panel 110 and the first cover portion 165a. Further, the fourth cover portion 165d may be disposed on an edge of the display panel 110 to dispose the light shielding member 150 between the first cover portion 165a and the fourth cover portion 165d. A distal end of the fourth cover portion 165d overlaps the first cover portion 165a at the first side portion 163a.

An insulating member 190 may further be disposed on the FPCB 115. The insulating member 190 may serve to reduce or effectively prevent the FPCB 115 from being exposed externally to thereby protect the FPCB 115.

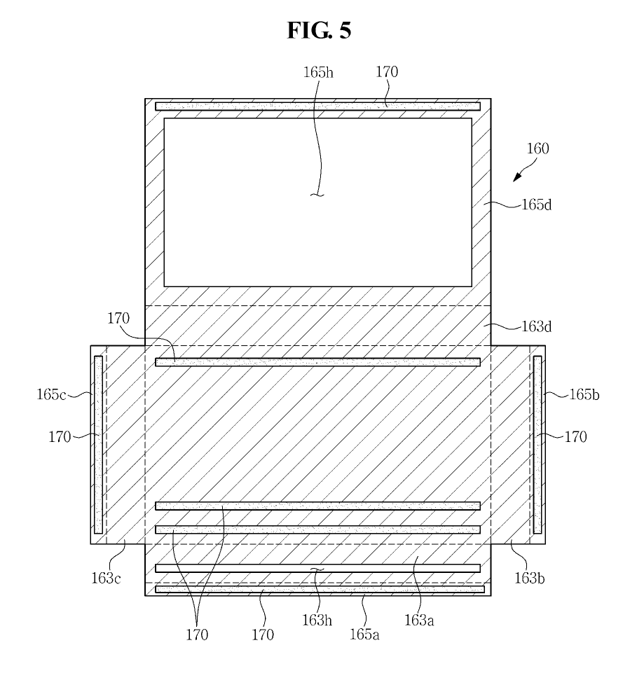

FIGS. 5, 6, 7, 8, and 9 are plan views illustrating an exemplary embodiment of a method of assembling a display device according to the invention.

Referring to FIG. 5, the adhesive member 170 may be disposed on the bottom portion 161 and the first, second, third and fourth cover portions 165a, 165b, 165c and 165d at distal ends thereof, of the accommodating member 160. In addition, the first side portion 163a of the accommodating member 160 may define the aperture 163h, and the fourth cover portion 165d of the accommodating member 160 may define the opening 165h. In an unassembled state of the accommodating member 160, the continuous surface thereof viewable in FIG. 5 (refer to diagonal hatched pattern) and on which the adhesive member 170 is disposed may be considered as inner surfaces of the accommodating member 160 in an assembled state thereof. As illustrated in FIG. 5, the adhesive member 170 is disposed at different portions of the same surface of the accommodating member 160. The same (hatched) surface of the accommodating member 160 is accessible for disposing components thereon at a same time and for each component of the display device.

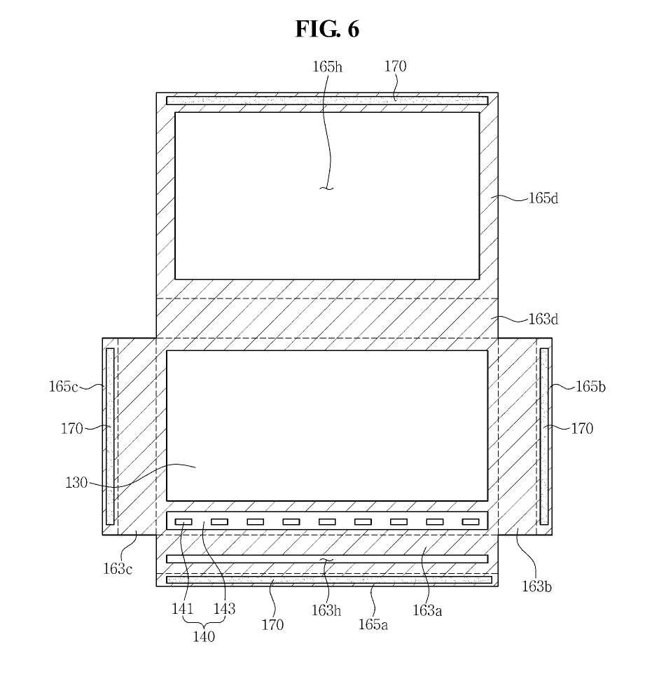

Referring to FIG. 6, the light guide plate 130 and the light source unit 140 may be attached to the bottom portion 161 of the accommodating member 160 via the adhesive member 170. Since, the light guide plate 130 and the light source unit 140 are disposed to overlap the adhesive member 170 previously disposed on the bottom portion 161, such adhesive member 170 is not visible in the view of FIG. 6.

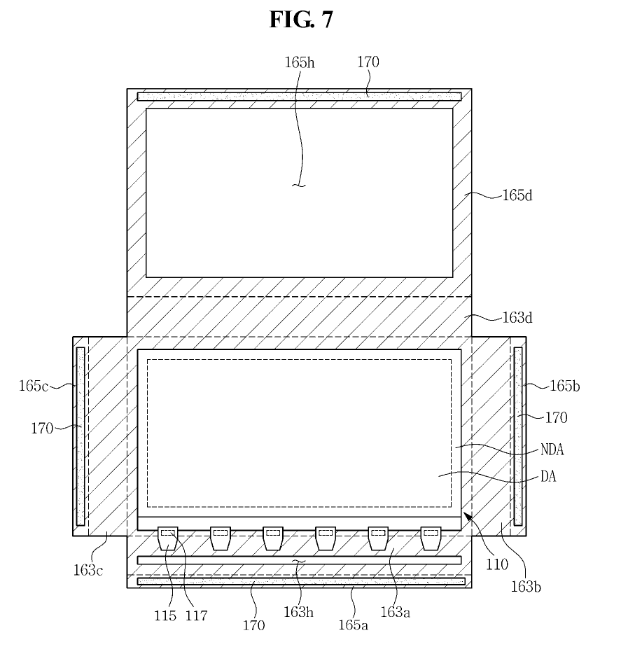

Referring to FIG. 7, an optical sheet (not illustrated) and the display panel 110 may be disposed on the light guide plate 130 which is disposed on the bottom portion 161. In this instance, a light shielding member (not illustrated) may further be disposed between the light source unit 140 which is disposed on the bottom portion 161 and the display panel 110, such that external leakage of light emitted from the light source unit 140 may be reduced or effectively prevented.

In disposing the display panel 110 on the light guide plate 130, the FPCB 115 extended from the display panel 110 and with the driving chip 117 thereon may overlap the first side portion 163a as illustrated in the plan view of FIG. 7. The display panel 110 includes a display area DA in which an image is displayed, and a non-display area NDA in which the image is not displayed. Length portions of the non-display area NDA are respectively extended at the first to fourth side portions 163a to 163d.

As illustrated in FIGS. 5-7, since the adhesive member 170 and other components of the display device are disposed different portions of the same surface of the accommodating member 160 in an un-assembled state thereof, the number of components of the display device may be reduced and the assembly of the components within the accommodating member 160 may be simplified such that manufacturing costs and a defect rate of the display device may be reduced.

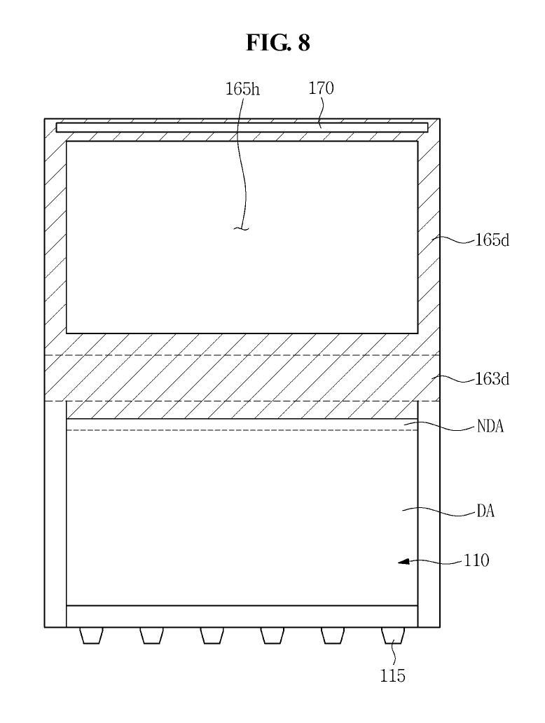

Referring to FIG. 8, the first side portion 163a and the first cover portion 165a of the accommodating member 160 may be folded based on the respective fold lines (indicated by the dotted lines in FIG. 8) so as to cover the portions of the non-display area NDA of the display panel 110 extended at the first side portion 163a. In this instance, the FPCB 115 extended from the display panel 110 may extend through the aperture 163h defined by the first side portion 163a to be externally exposed through the aperture 163h defined by the first side portion 163a. Subsequently, the second side portion 163b and the second cover portion 165b, and the third side portion 163c and the third cover portion 165c may be folded based on the respective fold lines so as to cover the portions of the non-display area NDA of the display panel 110 extended at the second and third side portions 163b and 163c.

Where the first through third side portions 163a to 163c and the first through third cover portions 165a to 165c are folded along the fold lines, the hatched surfaces thereof are not visible in the view of FIG. 8. Surfaces (un-hatched) of the first to third cover portions 165a to 165c opposite to the hatched surface thereof are visible in the view of FIG. 8. The surfaces of the first to third cover portions 165a to 165c visible in the view of FIG. 8 of may be considered as outer surfaces of the accommodating member 160 in an assembled state thereof.

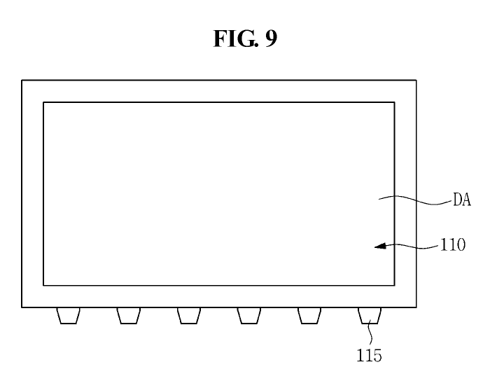

Referring to FIG. 9, the fourth side portion 163d and the fourth cover portion 165d may be folded based on the respective fold lines so as to cover the non-display area NDA of the display panel 110. In this instance, the display area DA of the display panel 110 may be externally exposed through the opening 165h defined by the fourth cover portion 165d. Where the fourth side portion 163d and the fourth cover portion 165d are folded along the fold lines, the hatched surfaces thereof are not visible in the view of FIG. 9. A surfaces (un-hatched) of the fourth cover portion 165d opposite to the hatched surface thereof is visible in the view of FIG. 9. The surface of the fourth cover portion 165d visible in the view of FIG. 9 of may be considered as an outer surface of the accommodating member 160 in an assembled state thereof.

As illustrated in FIGS. 8 and 9, since components of the display device are secured within within the display device by directly manipulation of portions of a single, unitary accommodating member 160, the number of components of the display device may be reduced and the assembly of the components within the accommodating member 160 may be simplified such that manufacturing costs and a defect rate of the display device may be reduced.

As set forth above, one or more exemplary embodiments of the display device may reduce the number of components to be configured therein, may simplify the assembly of the components therein, may reduce manufacturing costs thereof and may reduce a defect rate thereof.

From the foregoing, it will be appreciated that various exemplary embodiments in accordance with the present disclosure have been described herein for purposes of illustration, and that various modifications may be made without departing from the scope and spirit of the present teachings. Accordingly, the various exemplary embodiments disclosed herein are not intended to be limiting of the true scope and spirit of the present teachings. Various features of the above described and other embodiments can be mixed and matched in any manner, to produce further embodiments consistent with the invention.

What is claimed is:

1. A display device comprising:
a display panel comprising a display area in which an image is displayed and a non-display area around the display area and in which the image is not displayed; and
an accommodating member in which the display panel is accommodated, the accommodating member comprising a bottom portion on which the display panel is supported,
wherein
the bottom portion of the accommodating member extends to define a side portion of the accommodating member, the side portion bent from the bottom portion to cover a side surface of the display panel; and
the side portion defined by the extended bottom portion extends to define a cover portion of the accommodating member, the cover portion bent from the side portion to expose the display area of the display panel and to cover the non-display area of the display panel.

2. The display device of claim 1, further comprising a reflective member disposed on a surface of the accommodating member, the surface facing the display panel.

3. The display device of claim 2, wherein the reflective member is disposed on a surface of the bottom portion of the accommodating member.

4. The display device of claim 2, wherein the reflective member comprises one or more of aluminum (Al), silver (Ag), gold (Au), titanium oxide, aluminum paste, aluminum powder, silicon oxide, aluminum oxide, zirconium oxide, magnesium fluoride, barium sulfate and calcium carbonate.

5. The display device of claim 1, wherein the accommodating member is a reflective sheet.

6. The display device of claim 1, further comprising a flexible printed circuit board connected to the display panel,
wherein the side portion of the accommodating member defined by the extended bottom portion thereof defines an aperture through which the flexible printed circuit board extends.

7. The display device of claim 1, further comprising:
a flexible printed circuit board connected to the display panel, and
an insulating member on the flexible printed circuit board connected to the display panel,
wherein
the cover portion of the accommodating member defined by the extended side portion thereof, comprises a first cover portion extended from the side portion at a first side of the bottom portion and a second cover portion extended from the side portion at a second side of the bottom portion opposite to the first side thereof, the first and second cover portions overlapping each other in a cross-sectional thickness direction, and
in the cross-sectional thickness direction, the flexible printed circuit board connected to the display panel and the insulating member on the flexible printed circuit board connected to the display panel are each disposed between the overlapping first and second cover portions.

8. The display device of claim 1, further comprising a light source unit which is accommodated in the accommodating member and generates and provides light to the display panel.

9. The display device of claim 8, wherein the light source unit comprises a light source, and a light source substrate to which the light source is fixed.

10. The display device of claim 9, further comprising a fixing member between the accommodating member and the light source substrate, wherein the fixing member fixes the light source substrate to the accommodating member.

11. The display device of claim 9, wherein the accommodating member defines an aperture through which a portion of the light source substrate is exposed from the accommodating member.

12. The display device of claim 11, further comprising a heat dissipation member attached to the exposed portion of the light source substrate.

13. The display device of claim 1, further comprising a light guide plate between the display panel and the bottom portion of the accommodating member.

14. The display device of claim 13, further comprising a fixing member between the accommodating member and the light guide plate, wherein the fixing member fixes the light guide plate to the bottom portion of the accommodating member.

15. The display device of claim 13, further comprising an optical sheet between the display panel and the light guide plate fixed to the bottom portion of the accommodating member.

16. The display device of claim 13, further comprising:
a light source unit which is accommodated in the accommodating member and generates and provides light to the display panel, and
a light shielding member between the display panel and the light guide plate and between the display panel and light source unit.

17. The display device of claim 16, wherein
the cover portion of the accommodating member defined by the extended side portion thereof, comprises a first cover portion extended from the side portion at a first side of the bottom portion and a second cover portion extended from the side portion at a second side of the bottom portion opposite to the first side thereof, the first and second cover portions overlapping each other in a cross-sectional thickness direction, and
in the cross-sectional thickness direction, the first and second cover portions overlap each other at a same side of the light shielding member.

18. The display device of claim 16, wherein
the cover portion of the accommodating member defined by the extended side portion thereof, comprises a first cover portion extended from the side portion at a first side of the bottom portion and a second cover portion extended from the side portion at a second side of the bottom portion opposite to the first side thereof, the first and second cover portions overlapping each other in a cross-sectional thickness direction, and
in the cross-sectional thickness direction, the first and second cover portions overlap each other at opposing sides of the light shielding member.
